(19) United States
(12) Patent Application Publication
(10) Pub. No.: US 2006/0118332 A1
(43) Pub. Date: Jun. 8, 2006

(54) Multilayered circuit board for high-speed, differential signals

(75) Inventor: John E. Benham, Torrington, CT (US)

Correspondence Address: ROTHWELL, FIGG, ERNST & MANBECK, P.C., 1425 K STREET, N.W., SUITE 800, WASHINGTON, DC, 20005, US

(73) Assignee: Litton Systems, Inc., Los Angeles, CA (US)

(21) Appl. No.: 11/001,314

(22) Filed: Dec. 2, 2004

(51) Int. Cl. H05K 7/06

(52) U.S. Cl. 174/262

(57) ABSTRACT

The present invention provides a multilayered circuit board that can be used in high-density and high-speed electronic applications.

### BACKGROUND OF THE INVENTION

1. Field of the invention

The present invention relates to circuit boards, and, more specifically, to circuit boards for use in high-speed data applications.

2. Discussion of the Background

In recent years, accompanying the improvement in the processing power of computer and communications equipment, there has been an increasing demand for, among other things, circuit boards capable of high-speed data transmission.

Conventional high-speed, multi-layered circuit boards include vias (e.g., plated through holes or other vias) designed to electrically connect a compliant pin of an electrical connector to a transmission line (e.g., a signal trace) disposed between two internal layers of the circuit board. That is, in the conventional approach, the via that is used as the compliant pin interface is also used for electrical routing through the circuit board.

### SUMMARY OF THE INVENTION

We have discovered that the above described conventional circuit board design greatly impairs the integrity of the transmission path. What is desired, therefore, are circuit board that overcome this and other disadvantages of conventional circuit boards.

Accordingly, the present invention provides a circuit board design that overcomes disadvantages of conventional circuit board designs. In one aspect, the present invention provides a multilayered circuit board that can be used in, among other things, high-density and high-speed electronic applications.

A circuit board according to an embodiment of the present invention includes: a first complaint pin via for receiving a first compliant pin of a connector, the first compliant pin via extending through a first dielectric layer of the circuit board; a second complaint pin via for receiving a second compliant pin, the second compliant pin via extending through the first dielectric layer; a first signal via electrically connected to a first transmission line disposed between a second and third dielectric layer of the circuit board, wherein the second dielectric layer is below the first dielectric layer and the third dielectric layer is below the second dielectric layer; a second signal via electrically connected to a second transmission line disposed between the second and third dielectric layers; a first link trace electrically connecting the first compliant pin via to the first signal via, the first link trace being disposed between the first and second dielectric layers; and a second link trace electrically connecting the second compliant pin via to the second signal via, the second link trace also being disposed between the first and second dielectric layers.

The first and second link traces may be disposed on a top surface of the second dielectric layer and the first and second transmission lines may each comprise a strip of electrically conducting material that are disposed on the third dielectric layer.

In some embodiments, a longitudinal axis of the first compliant pin via and a longitudinal axis of the second compliant pin via lie on a first plane, and a longitudinal axis of the first signal via and a longitudinal axis of the second signal via lie on a second plane, wherein the second plane is spaced apart from the first plane and is parallel with the first plane. Advantageously, the second plane may be spaced apart from the first plane by a distance, wherein the distance is less than a length of the first link trace and less than a length of the second link trace. Preferably, the length of the first link trace is equal to the length of the second link trace.

Also, in some embodiments, the circuit board may include a conducting layer disposed on top of the first dielectric layer, wherein the first and second complaint pin vias extend through the conducting layer and are isolated therefrom by an anitpad. The circuit board may also include a conducting layer disposed between the second dielectric layer and the third dielectric layer, in which case there is preferably a fourth dielectric layer disposed between the conducting layer and the third dielectric layer.

Advantageously, in some embodiments, the distance between the first and second compliant pin vias is less than the distance between the first and second signal vias.

The above and other features and advantages of the present invention, as well as the structure and operation of preferred embodiments of the present invention, are described in detail below with reference to the accompanying drawings.

### BRIEF DESCRIPTION OF THE DRAWINGS

The accompanying drawings, which are incorporated herein and form part of the specification, help illustrate various embodiments of the present invention and, together with the description, further serve to explain the principles of the invention and to enable a person skilled in the pertinent art to make and use the invention. In the drawings, like reference numbers indicate identical or functionally similar elements. Additionally, the left-most digit(s) of a reference number identifies the drawing in which the reference number first appears.

FIG. 1 is a cross sectional view of a portion of a circuit board according to an embodiment of the present invention.

FIG. 2 is a top view, according to one embodiment, of a top ground layer of the circuit board.

FIGS. 3A-C are a views of the circuit board, according to one embodiment, with layers removed so that the connections among compliant pin vias, signal vias, link traces and transmission lines can be more easily seen.

FIG. 4 shows a top view, according to one embodiment, of an internal dielectric layer of the circuit board.

FIG. 5 shows a top view, according to one embodiment, of an internal ground layer of the circuit board.

FIG. 6 shows a top view of a layer of a circuit board according to an embodiment of the invention.

### DETAILED DESCRIPTION OF THE PREFERRED EMBODIMENT

The present invention provides a multilayered circuit board for use in high-speed data applications.

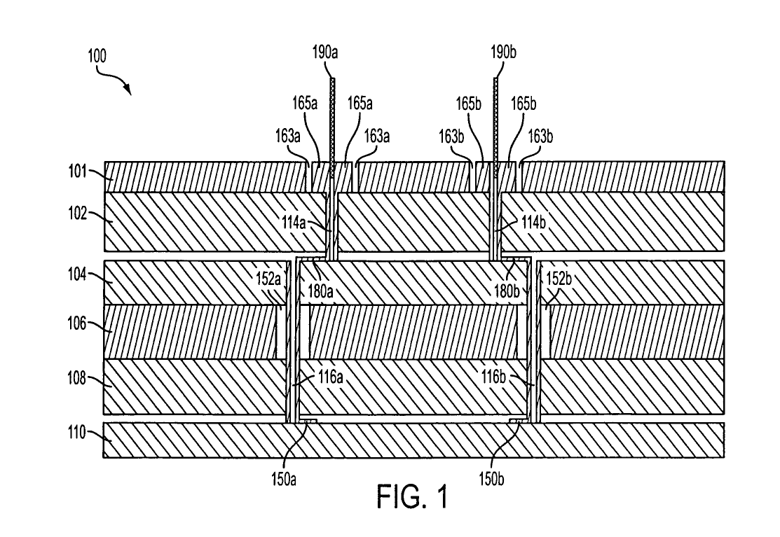

FIG. 1 is a cross-sectional side view of a portion of a multilayered circuit board 100 according to an embodiment of the present invention. In the embodiment shown, circuit board 100 includes a top dielectric thickness or “layer” 102, a second dielectric layer 104 below first dielectric layer 102, a third dielectric layer 108 disposed below second dielectric layer 104, and a fourth dielectric layer 110 below second dielectric layer 104. This will continue to route all position of the connector.

As shown in FIG. 1, a first ground layer 101, which is made of an electrically conducting material (e.g., copper), may be disposed on dielectric layer 102 and a second ground layer 106 may be disposed between dielectric layers 104 and 108. As also shown in FIG. 1, a first compliant pin via 114a and a second compliant pin via 114b extend through ground layer 101 and dielectric layer 102. A capture pad 165 may surround compliant pin via 114a and a capture pad 165b may surround compliant pin via 114b.

In one embodiment, circuit board 100 is designed to be used to transmit differential signals. Accordingly, in one embodiment, each compliant pin via is paired with another compliant pin via to form a differential via pair. For example, compliant pin vias 114a&b form a differential via pair.

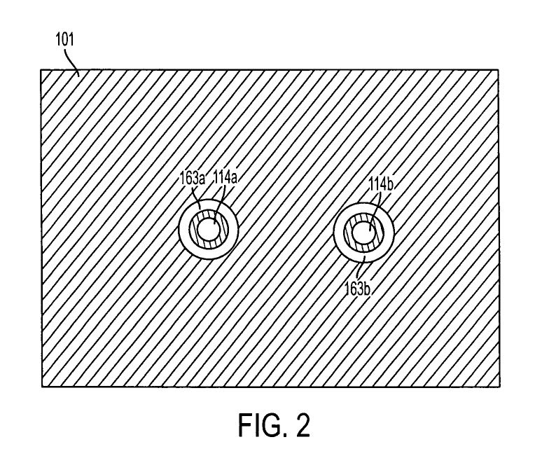

FIG. 2 illustrates a top view of circuit board 100. As shown in FIG. 2, the compliant pin vias 114 are surrounded by and electrically isolated from the ground plane 101. For example, a clear cut or anti-pad 163 (or other dielectric substance) surrounds a top portion of each compliant pin via 114, thereby electrically isolating the compliant pin vias 114 from the surrounding ground plane 101. In some embodiments, compliant pin vias 114 may be plated with nickel and/or gold. Preferably, the antipads 163 are sized to control the unique inductance (L) and capacitance (C) elements of the compliant pins.

Referring back to FIG. 1, as shown, each compliant pin via 114 extends through one or more layers of circuit board 100. Preferably, however, each compliant pin via 114 extends only through the ground layer 101 (if any) and the top dielectric layer 102. Each compliant pin via 114 functions to receive a compliant pin of a connector and to electrically connect the compliant pin to a first transmission line (a.k.a., a “link trace”) located on a layer within the circuit board 100. For example, compliant pin via 114a receives pin 190 a and electrically couples pin 190 a with link trace 180a, and compliant pin via 114b receives pin 190b and electrically couples pin 190b with link trace 180b.

Link trace 180 a functions to electrically connect compliant pin via 114a to a signal via 116a. Similarly, link trace 180b functions to electrically connect compliant pin via 114a to a signal via 116a. Signal vias 116 extend through one or more layers of circuit board 100. As shown in the embodiment illustrated in FIG. 1, signal vias 116 extend through layers 104, 106 and 108. Signal via 116a functions to electrically connect link trace 180a, and hence pin 190a, to a transmission line 150 a that is located on a lower layer of circuit board 100 (e.g., on layer 110). Similarly, signal via 116b functions to electrically connect link trace 180b, and hence pin 190b, to a transmission line 150b that is located on layer 110.

In some embodiments, the length of the compliant pin vias is shorter than the length of the signal vias. For example in some embodiments, the length of the compliant pin vias generally ranges between 0.02 and 0.06 inches, whereas the length of the signal vias generally ranges between 0.03 and 0.07 inches.

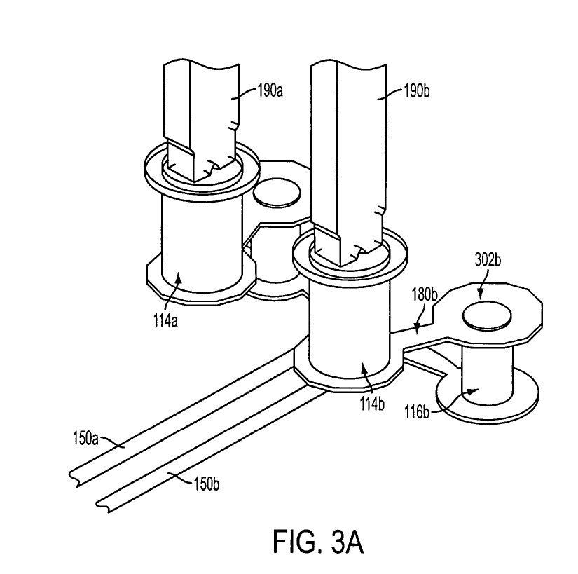

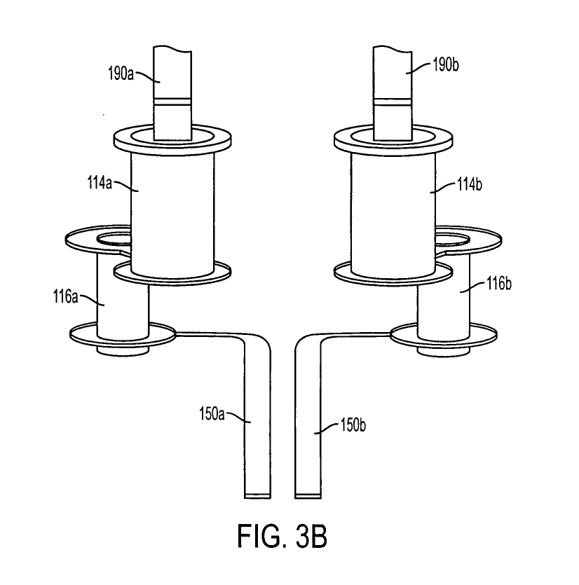

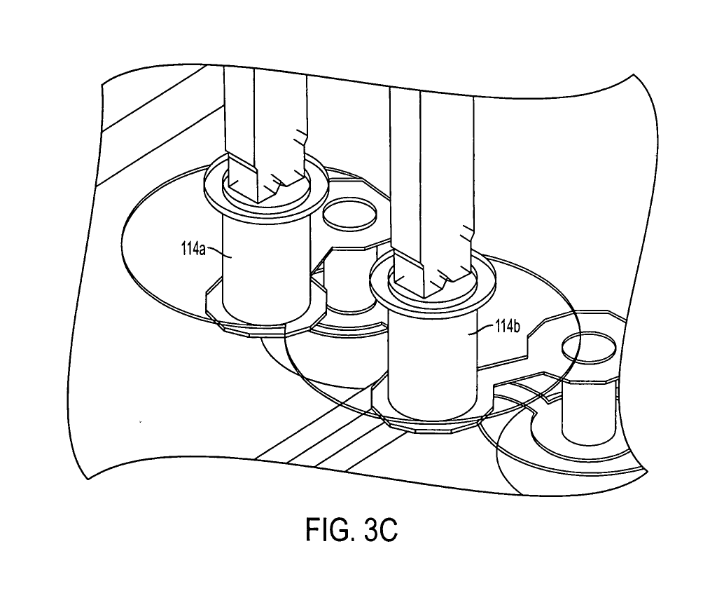

Referring now to FIGS. 3A-D, FIGS. 3A-D are views of circuit board 100 with layers 101-110 removed so that the connections and relationships among compliant pin vias 114, signal vias 118, link traces 180 and transmission lines 150 can be more easily seen.

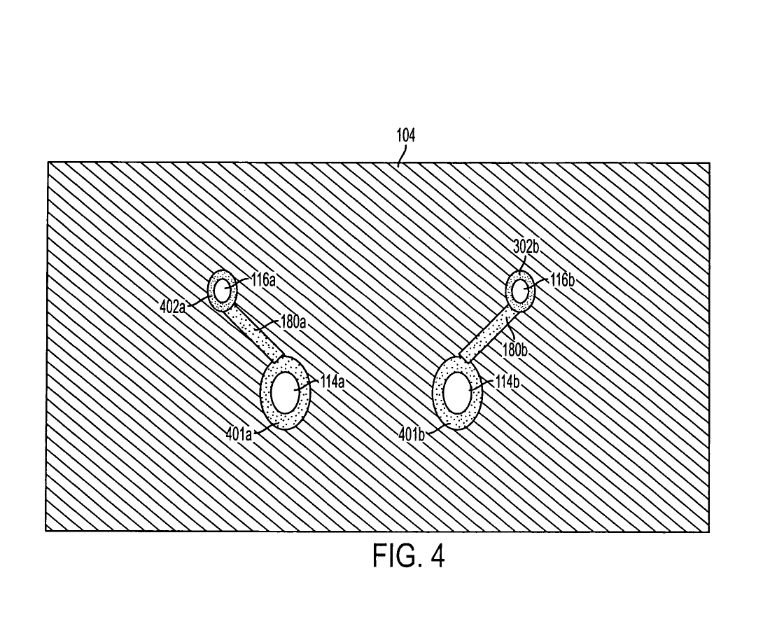

Referring now to FIG. 4, FIG. 4 shows a top view of dielectric layer 104. This view illustrates the offset spatial relationship between compliant pin vias 114 and signal vias 116. This view also illustrates link traces 180. As shown in FIG. 4, link trace 180 a is connected between compliant pin via 114a and signal via 116a, thereby electrically connecting via 114a with 116a. Similarly, link trace 180b is connected between compliant pin via 114b and signal via 116b, thereby electrically connecting via 114b with 116b. Capture pads 401a and 402a may surround vias 114a and 116a, respectively, to facilitate link trace 180 a in making the electrical connection between vias 114a and 116a. Similarly, capture pads 401b and 302b may surround vias 114b and 116b, respectively, to facilitate link trace 180b in making the electrical connection between vias 114b and 116b.

In some embodiments, as shown in FIG. 4, signal vias 116 are offset from compliant pin vias 114. That is, signal vias 116 are not aligned with compliant pin vias 114. In one embodiment, the longitudinal axis of compliant pin via 114a and the longitudinal axis of compliant pin via 114b lie in a first plane, and the longitudinal axis of signal via 116a and the longitudinal axis of signal via 116b lie in a second plane that is parallel with and spaced apart from the first plane. The distance between the two planes may be less than the length of either link trace.

Additionally, it is preferred that the distance between compliant pin vias 114a&b be less than the distance between signal vias 116a&b, as shown in FIG. 4. For example, the distance between compliant pin vias 114a&b may range from 0.04 to 0.07 inches, while the distance between signal vias 116a&b may range from 0.06 to 0.1 inches. It is also preferred that link traces 180 be relatively short. For example, it is preferred that the length of the link traces 180 be one half the row pitch of the connector. Further, the diameter of complaint pin vias 114 may be greater than the diameter of signal vias 118. For example, the diameter of compliant pin vias 114 may range between 0.014 and 0.028 inches, whereas the diameter of signal vias 116 may range between 0.012 and 0.026 inches.

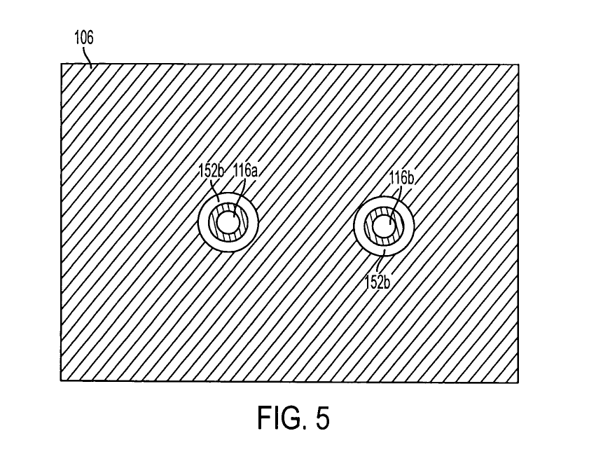

Referring now to FIG. 5, FIG. 5 is a top view of ground layer 106. FIG. 5 shows that signal vias 116a-b pass through ground layer 106 and are isolated from ground layer 106 by antipads 152a-b, respectively. Preferably, the antipads 152 are sized to control the unique L and C elements of the compliant pins. Advantageously, the compliant and signal vias are independently tuned with the respective antipads.

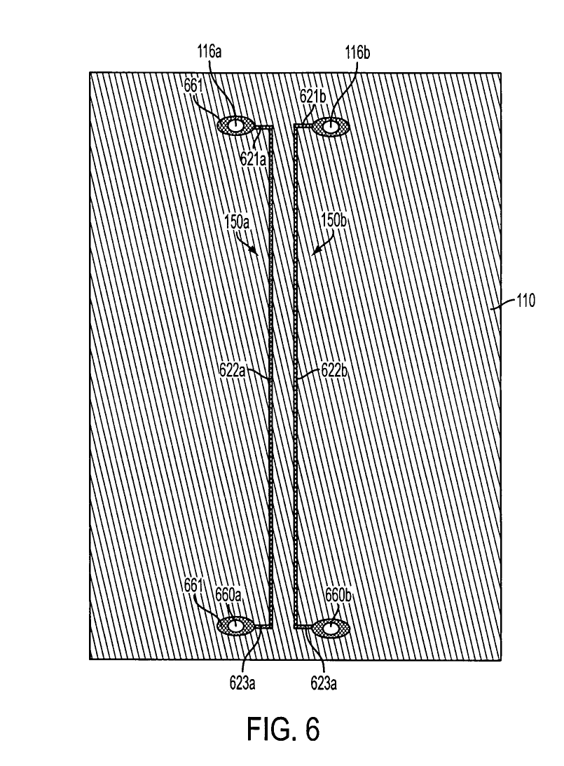

Referring now to FIG. 6, FIG. 6 shows a top view of layer 110, according to an embodiment. FIG. 6 illustrates that signal vias 116a-b are electrically connected to transmission lines 150a-b, respectively. Thus, signal vias 116a-b, serve to electrically connect compliant pins 190a-b to transmission lines 150a-b, respectively. In embodiments where circuit board 100 is used to transmit differential signals, transmission lines 150a-b form a differential transmission path.

Preferably, as shown in FIG. 6, each transmission line 150 has three sections: a first end section 621, a second end section 623, and an interim section 622 between the first end section 621 and the second end 623. In the embodiment shown, the interim section 622 of each transmission line 150 is straight and they are parallel with each other. Additionally, the interim sections 622 are substantially longer than the end sections 621,623.

Also, in the embodiment shown, first end section 621a of transmission line 150 a is connected to signal via 116a through a capture pad 661 and the second end section 623a of transmission line 150 a is connected to a signal via 660 a through a capture pad 662. Similarly, first end section 621b of transmission line 150b eis connected to signal via 116b through a capture pad and the second end section 623b of transmission line 150b is connected to a signal via 660b through a capture pad. In this manner, the signal vias 116a and 660 a are electrically connected and signal vias 116b and 660b are electrically connected.

In one embodiment, for each transmission line 150, neither the first nor second end sections 621 and 623 are aligned with interim section 622. Instead, the end sections 621, 623 are angled with respect to the interim section 622. In the embodiment shown in FIG. 6, the end sections 621, 623 are angled at or about 90 degrees with respect to the interim section (i.e., they are perpendicular to the interim section). However, other angles are contemplated.

Preferably, the distance between signal vias 116a-b is greater than the distance between the interim sections of the transmission lines connected to the signal vias. This feature is illustrated in FIG. 6. As shown in FIG. 6, for example, the distance between signal vias 116a and 116b is greater than the distance between the interim section of transmission line 150 a and the interim section of transmission line 150b. In some embodiments, the distance between a differential pair of signal vias is generally 0.080 inches and the distance between the interim sections of the transmission lines connected to the vias is generally 0.010 inches.

In some embodiments, it is also preferred that the distance between a pair of signal vias connected by a transmission line of a differential path is equal or about equal to the length of the interim section of the transmission line. For example, as shown in FIG. 6, the distance between signal via 116a and signal via 660 a is equal to or about equal to the length of the interim section of transmission line 150a.

Although the figures illustrate only a single pair of complaint pin vias, link traces, signal vias, and transmission lines, it is contemplated that circuit board 100 would have a number of compliant pin pairs and corresponding link traces, signal vias and transmission lines.

Further, while various embodiments of the present invention have been described above, it should be understood that they have been presented by way of example only, and not limitation. Thus, the breadth and scope of the present invention should not be limited by any of the above-described exemplary embodiments, but should be defined only in accordance with the following claims and their equivalents.

What is claimed is:

1. A circuit board, comprising:
a first complaint pin via for receiving a first compliant pin of a connector, the first compliant pin via extending through a first dielectric layer of the circuit board;
a second complaint pin via for receiving a second compliant pin of the connector, the second compliant pin via extending through said first dielectric layer;
a first signal via electrically connected to a first transmission line disposed between a second and third dielectric layer of the circuit board, wherein the second dielectric layer is below the first dielectric layer and the third dielectric layer is below the second dielectric layer;
a second signal via electrically connected to a second transmission line disposed between the second and third dielectric layers;
a first link trace electrically connecting the first compliant pin via to the first signal via, the first link trace being disposed between the first and second dielectric layers; and
a second link trace electrically connecting the second compliant pin via to the second signal via, the second link trace being disposed between the first and second dielectric layers.

2. The circuit board of claim 1, wherein the first and second link traces are disposed on a top surface of the second dielectric layer.

3. The circuit board of claim 1, wherein the first and second transmission lines each comprise a strip of electrically conducting material.

4. The circuit board of claim 3, wherein the strips are disposed on the third dielectric layer.

5. The circuit board of claim 1, wherein a longitudinal axis of the first compliant pin via and a longitudinal axis of the second compliant pin via lie on a first plane, and a longitudinal axis of the first signal via and a longitudinal axis of the second signal via lie on a second plane, wherein the second plane is spaced apart from the first plane and is parallel with the first plane.

6. The circuit board of claim 5, the second plane is spaced apart from the first plane by a distance, wherein the distance is less than a length of the first link trace and less than a length of the second link trace.

7. The circuit board of claim 6, wherein the length of the first link trace is equal to the length of the second link trace.

8. The circuit board of claim 1, further comprising a conducting layer disposed on top of the first dielectric layer, wherein the first and second complaint pin vias extend through the conducting layer and are isolated therefrom by an anitpad.

9. The circuit board of claim 1, further comprising a conducting layer disposed between the second dielectric layer and the third dielectric layer.

10. The circuit board of claim 9, further comprising a fourth dielectric layer disposed between the conducting layer and the third dielectric layer.

11. The circuit board of claim 1, wherein the distance between the first and second compliant pin vias is less than the distance between the first and second signal vias.

12. A circuit board, comprising:
a first complaint pin via for receiving a first compliant pin of a connector;
a second complaint pin via for receiving a second compliant pin of the connector;
a first signal via electrically connected to a first transmission line;
a second signal via electrically connected to a second transmission line;
a first link trace electrically connecting the first compliant pin via to the first signal via; and
a second link trace electrically connecting the second compliant pin via to the second signal via.

13. The circuit board of claim 12, wherein the first and second transmission lines each comprise a strip of electrically conducting material.

14. The circuit board of claim 12, wherein a longitudinal axis of the first compliant pin via and a longitudinal axis of the second compliant pin via lie on a first plane, and a longitudinal axis of the first signal via and a longitudinal axis of the second signal via lie on a second plane, wherein the second plane is spaced apart from the first plane and is parallel with the first plane.

15. The circuit board of claim 14, the second plane is spaced apart from the first plane by a distance, wherein the distance is less than a length of the first link trace and less than a length of the second link trace.

16. The circuit board of claim 15, wherein the length of the first link trace is equal to the length of the second link trace.

17. The circuit board of claim 12, further comprising a conducting layer disposed on top of a first dielectric layer, wherein the first and second complaint pin vias extend through the conducting layer and are isolated therefrom by an anitpad and extend through the first dielectric layer.

18. The circuit board of claim 12, wherein the distance between the first and second compliant pin vias is less than the distance between the first and second signal vias.

19. The circuit board of claim 12, wherein the signal vias and the compliant pin vias are independently tuned with antipads.
